(19) United States
(12) Patent Application Publication
(10) Pub. No.: US 2006/0189023 A1
(43) Pub. Date: Aug. 24, 2006

(54) Three dimensional structure formed by using an adhesive silicon wafer process

(75) Inventors: Fa-Yuan Chang, Taipei (TW); Hua-Shu Wu, Hsin-Chu (TW); Tsung-Mu Lai, Jhubei City (TW); Chau-Yang Wu, Taipei (TW)

Correspondence Address: TUNG & ASSOCIATES;Suite 120, 838 W. Long Lake Road, Bloomfield Hills, MI, 48302, US

(73) Assignee: Taiwan Semiconductor Manufacturing Co., Ltd.

(21) Appl. No.: 11/064,985

(22) Filed: Feb. 23, 2005

(51) Int. Cl. H01L 21/46

(52) U.S. Cl. 438/69; 438/455; 438/459; 438/458

(57) ABSTRACT

A method of making a MEMS device including providing a first substrate with an insulator layer thereon. A holder is attached to the insulator layer, and the first substrate is thinned. Thereafter, cavities are formed in the first substrate and the first substrate is flipped over and bonded to an integrated circuit wafer with the cavities facing the integrated circuit wafer. The holder is removed to provide a first substrate with cavities formed therein facing the integrated circuit wafer and an insulator layer overlying the first substrate.

### FIELD OF THE INVENTION

This invention relates to micro-electro-mechanical systems (MEMS). In particular, the invention relates to a method of fabricating a MEMS using silicon-on-insulator.

### BACKGROUND OF THE INVENTION

One form of vertical device isolation is known as silicon-on-insulator (SOI). SOI technology is based upon an insulator layer (silicon dioxide) buried within the silicon that electrically isolates devices on the silicon surface. Although SOI technology is relatively old, it has not seen wide use due to the process complexity and cost associated with SOI technology. SOI offers several advantages for deep submicron CMOS applications, including completely eliminating latchup, reduced electrical fields to minimize hot carriers and to reduce parasitic capacitance. One SOI process involves forming single-crystal silicon on an oxide layer (or other insulator material) but it is difficult to accomplish because the dielectric materials crystalline properties are so different from pure silicon. If this type of SOI process is not properly controlled, the difference in crystalline structure can lead to crystal defects on the silicon that effect the device's performance. A more widely used SOI technology is known as SIMOX. In the SIMOX (Separation by IMplanted OXygen) process, a well-defined horizontal oxide layer is buried in the silicon wafer. This is done by implanting a high concentration of oxygen atoms into the wafer, typically using a high-energy implanter (e.g., a 200 keV oxygen implanter). The implanter step is followed by a high-temperature thermal anneal (e.g., 1300 degrees Celsius) to react the buried oxygen within the silicon to form a continuous silicon dioxide layer under the thin silicon surface. This buried oxide (referred to as BOX) layer is typically about 50 to 500 nm thick and serves as an excellent device isolation layer. The buried oxide process also generates the crystalline quality of the silicon layer remaining over the oxide. There are also new SIMOX techniques in development using low-energy, low-dose oxygen implanters that produce buried layers with improved dielectric properties.

Rajan, et al., U.S. Patent Application No. 2003/0169962, published Sep. 11, 2003 discloses a mirror SOI wafer including a silicon substrate, typically a single-crystal silicon wafer, a buried silicon dioxide or oxide layer, grown on the silicon substrate, by oxidation or chemical vapor deposition, and a thin polycrystalline p+ silicon layer grown on the oxide layer. An optional protective oxide layer may be grown on the backside of a silicon wafer. The silicon substrate may serve as a sacrificial handle layer and is etched away.

Behin, et al., U.S. Patent Application No. 2002/0064337, published May 30, 2002 discloses a MEMS mirror. Disclosed is an apparatus including a base and a flap coupled to the base, for example by one or more fixtures so that the flap is movable out of the plane of the base from a first angular orientation to a second angular orientation. The flap may include a light-deflecting element so that the apparatus may operate as a MEMS optical switch. The flap and the base are formed from a portion of a starting material in order to avoid alignment problems associated with post-process bonding associated with a two-wafer approach. The starting material may be formed from a silicon-on-insulator (SOI) wafer having a device layer, an insulator layer, and a substrate layer as the base. This starting material may include an opening for a cavity having side walls that are vertical and perpendicular to the plane of the base. The flap, fixtures and side walls may be positioned so that the bottom portion of the flap contacts one of the side walls when the flap is in the second angular orientation such that the flap may assume an orientation substantially parallel to that of the side walls.

FIGS. 1A-D illustrates a method of making a MEMS device using a SOI wafer. As shown in FIG. 1A, the process begins by providing a SOI wafer having a first silicon portion 12 and a second silicon portion 14. The first silicon portion 12 and the second silicon portion 14 are isolated by an insulator layer 16, which typically is a silicon dioxide layer. The first silicon portion 12 includes a bottom face 18 and the second silicon portion 14 includes a top face 20. As shown in FIG. 1B, a plurality of cavities 22 are formed on the top face 20 of the second silicon portion 14. This may be accomplished using standard photolithography methods. As shown in FIG. 1C, thereafter the SOI wafer 10 is flipped over and bonded to an integrated circuit wafer 24, so that the cavities 22 face a top surface 25 of the integrated circuit wafer 24 and so that the top surface 20 of the second silicon portion 14 engages the top surface 25 of the integrated circuit wafer 24. As shown in FIG. 1D, thereafter the first silicon portion 12 may be thinned and completely removed to leave the silicon dioxide insulator layer 16. Such a process may be utilized to make a micromirror display semiconductor device wherein the cavities 22 form a space into which a micromirror may be deflected.

The present invention provides alternatives to the prior art.

### SUMMARY OF THE INVENTION

The present invention includes a method of making a MEMS device including providing a first substrate with an insulator layer thereon. A holder is attached to the insulator layer, and the first substrate is thinned. Thereafter, cavities are formed on the first substrate and the first substrate is flipped over and bonded to an integrated circuit wafer, with the cavities facing the integrated circuit wafer. The holder is removed to provide a first substrate with cavities formed therein facing the integrated circuit wafer and an insulator layer overlying the first substrate.

These and other embodiments of the invention will become apparent from the following brief description of the drawings, detailed description of exemplary embodiments, and appended claims and drawings.

### BRIEF DESCRIPTION OF THE DRAWINGS

FIG. 1A illustrates a method including providing a SOI wafer having a first silicon portion and a second silicon portion separated by an insulator layer.

FIG. 1B illustrates a method including forming cavities in the second silicon portion of FIG. 1A.

FIG. 1C illustrates a method including bonding the SOI wafer to an integrated circuit wafer with the cavities facing the integrated circuit wafer.

FIG. 1D illustrates a method including thinning the first silicon portion of FIG. 1C.

FIG. 2A illustrates a method according to one embodiment of the present invention including providing a device including a first substrate and an insulator layer on the first substrate.

FIG. 2B illustrates a method according to one embodiment of the present invention including attaching a holder to the insulator layer of the device illustrated in FIG. 2A.

FIG. 2C illustrates a method according to one embodiment of the present invention including thinning the first substrate.

FIG. 2D illustrates a method according to one embodiment of the present invention including selectively forming and patterning a photo resist layer on the first substrate of FIG. 2C with openings formed in the photo resist layer.

FIG. 2E illustrates a method according to one embodiment of the present invention including forming cavities by etching the exposed portions not covered by the photo resist layer in FIG. 2D.

FIG. 2F illustrates a method according to one embodiment of the present invention including attaching a first substrate to an integrated circuit wafer with the cavities facing the integrated circuit wafer.

FIG. 3 illustrates a plan view, with portions broken away, of a MEMS device according to one embodiment of the invention.

FIG. 4 illustrates a side view, with portions broken away, of a MEMS device according to one embodiment of the invention.

FIG. 5 illustrates a projector display system including an array of micromirrors formed using a process according to the present invention.

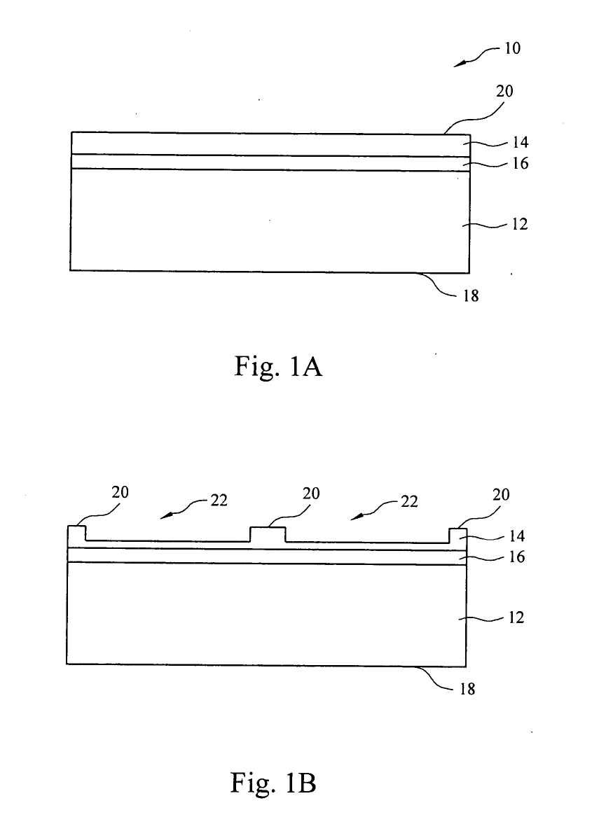

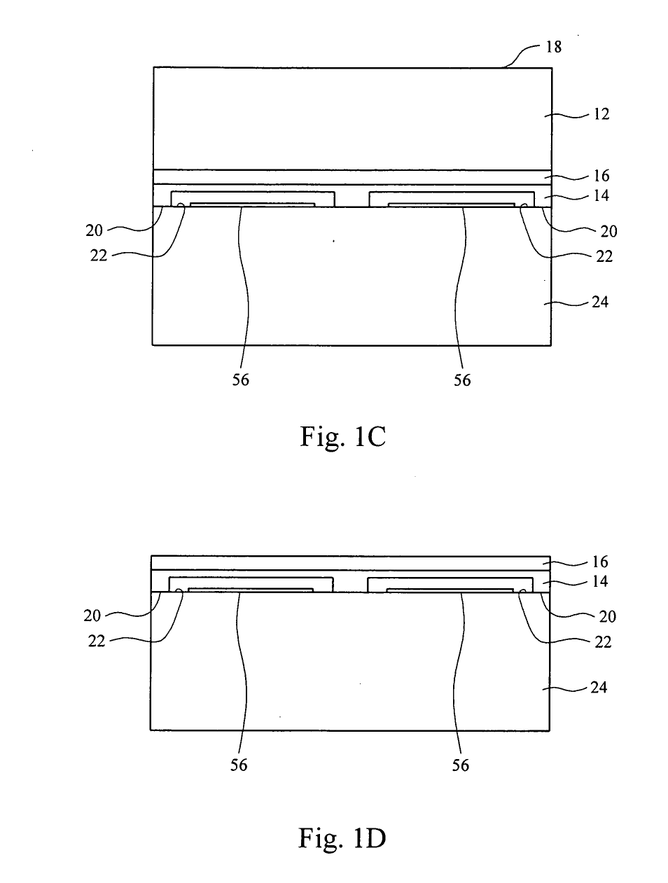

### DETAILED DESCRIPTION OF THE INVENTION

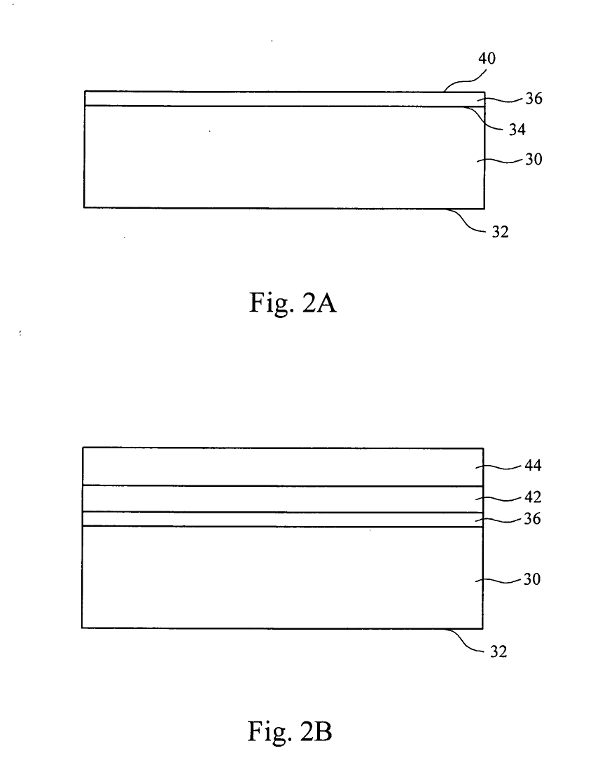

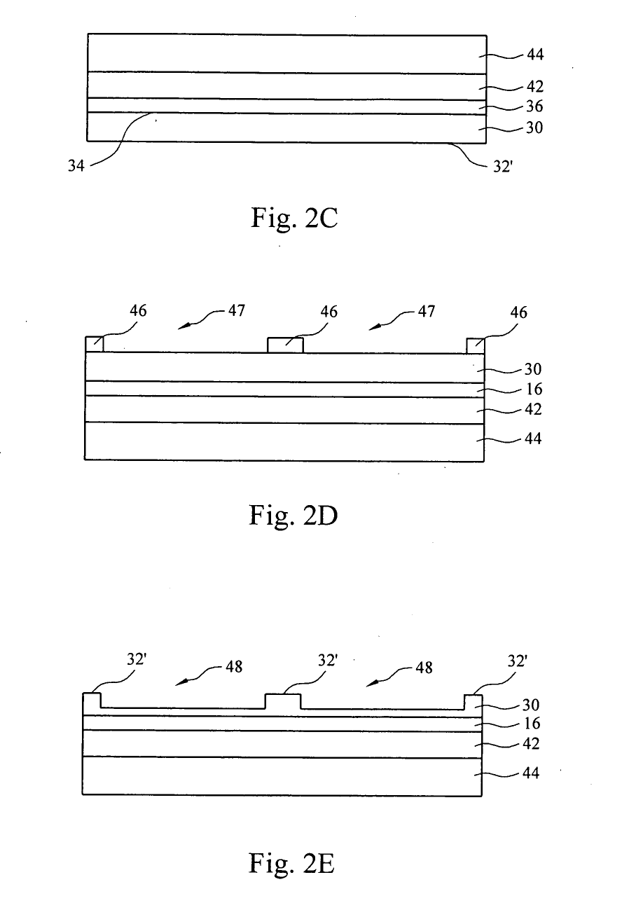

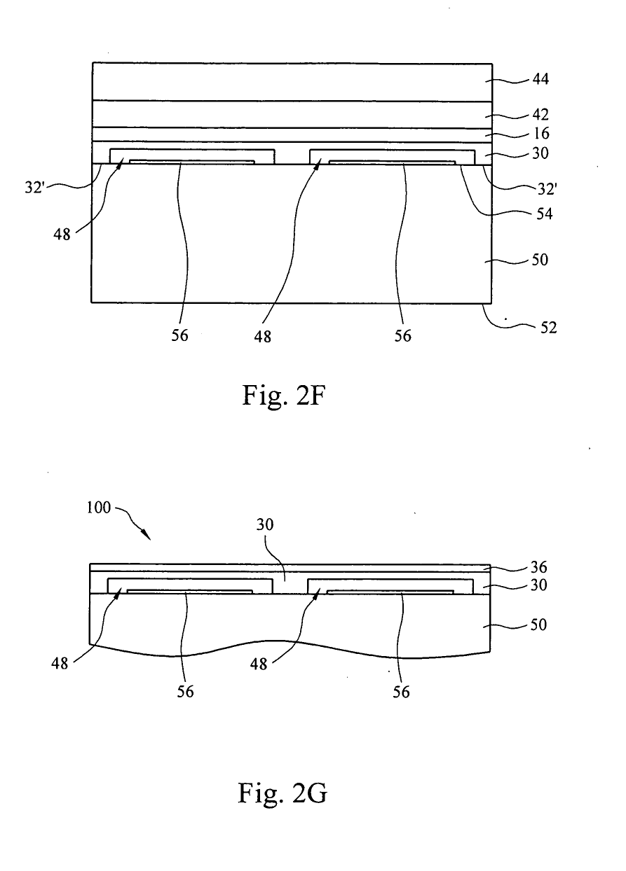

One embodiment of the invention includes providing a first substrate 30, which may be a wafer comprising silicon. The first substrate 30 may have a bottom face 32 and a top face 34. An insulator layer 36 may overlie the top face 34 of the first substrate 30. In one embodiment the insulator layer 36 has a bottom face 38 which may be in direct contact with the top face 34 of the first substrate 30. The insulator layer 36 may also have a top face 40. In one embodiment the insulator layer 36 may include silicon dioxide which may be deposited, grown, or provided in any manner known to those skilled in the art. In one embodiment, no additional (or second) silicon portion is provided overlying the insulator layer 36. Referring now to FIG. 2B, in one embodiment of the invention, a holder 44 is attached to at least one of the first substrate 30 and the insulator layer 36. In a preferred embodiment, the holder 44 is a wafer comprising silicon that is attached to the top face 40 of the insulator layer 36 by depositing an adhesive layer 42 over the top face 40 of the insulator layer 36 and then placing the holder 44 on top of the adhesive layer 42 and allowing the adhesive layer 42 to cure.

Referring now to FIG. 2C, thereafter, the first substrate 30 may be thinned (i.e., reduced in thickness) by for example, including but not limited to, chemical mechanical planarization, grinding and plasma thinning of the first substrate 30. The first substrate 30 now has a post thinning face 32′ (third face).

Referring now to FIG. 2D, the wafer holder 44 with the first substrate 30 may be flipped over and a photo resist layer 46 may be selectively deposited and patterned to provide openings 47 therein exposing portions of the third face 32′ of the first substrate 30. The exposed portions of the third face 32′ may be etched through the openings 47 to provide cavities 48 in the first substrate 30, as shown in FIG. 2E. The cavities 48 in the first substrate 30 may be formed by wet or dry etching, or by reactive ion etching, or by any other suitable means known to those skilled in the art.

Referring again to FIG. 2F, the wafer holder 44 may be utilized to bond the first substrate 30 to a second substrate 50. In one embodiment, the third face 32′ is bonded directly to a top face 54 of the second substrate 50. The second substrate 50 may also have a bottom face 52. In one embodiment, the second substrate 50 is a semiconductor wafer include a plurality of integrated circuits defined therein. The substrate 50 may also include at least one electrode 56 aligned with one of the cavities 48 formed in the first substrate 30.

Referring now to FIG. 2G, thereafter, the wafer holder 44 and the adhesive layer 42 may be removed to provide a MEMS device 100. The wafer holder 44 and the adhesive layer 42 may be removed by, for example, including but not limited to, etching the same. Optionally, the insulator layer 36 may also be removed, for example by etching.

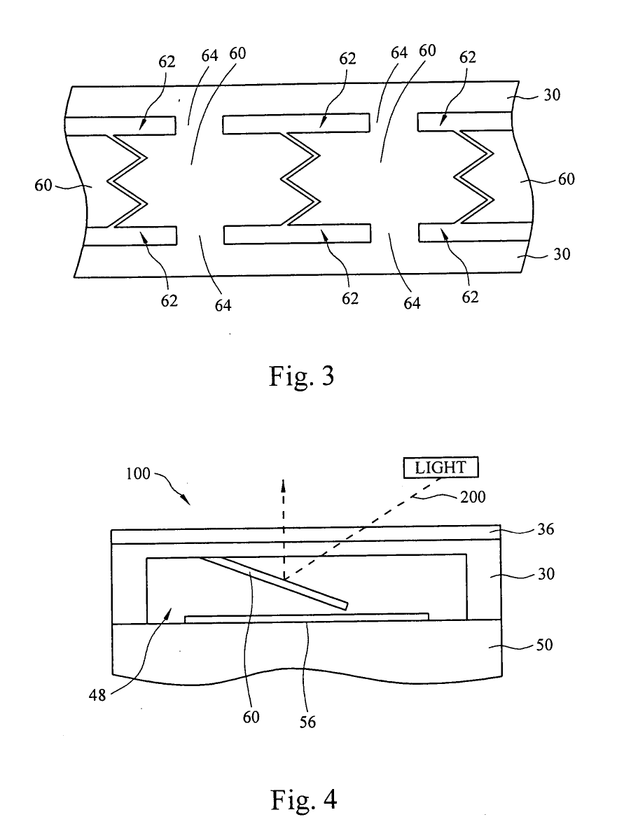

Referring now to FIG. 3, a plurality of micromirrors 60 may be formed in the first substrate 30 and/or the insulator layer 36. The micromirrors 60 may be formed by depositing a reflective layer (not shown), onto the insulator layer 36, or onto the first substrate 30, if portions of the insulator layer 36 have been removed. The micromirror may include a light reflecting material such as, but not limited to, at least one of aluminum or silver. In one embodiment, the reflective layer may be 100-500 angstroms thick, and preferably 200-400 angstroms thick, and most preferably 300 angstroms thick. In one embodiment, the reflective layer includes aluminum, silver, and copper. In one embodiment, the reflective layer includes 98.5 weight percent aluminum, one weight percent silicon, and 0.5 weight percent copper. The reflective layer may be formed by any method known to those skilled in the art, including screen printing, chemical vapor deposition, by securing a foil to the insulator layer 36, the first substrate 30, or an additional layer such as silicon nitride formed over either 36 or 30. Preferably, the reflective layer is formed by sputtering a reflective material onto the insulator layer 36 or the first substrate 30. Portions of the reflective layer and the insulator layer 36 and the first substrate 30 may be removed, for example by etching to provide spaces 62 which separate the micromirror 60 from the rest of the first substrate 30 or the insulator layer 36, with the exception of a torsion hinge 64 which may be provided connecting the micromirror for pivotal movement. The torsion hinge 64 may be made from for example, including but not limited to, one of the first substrate 30 or insulator layer 36.

Referring now to FIG. 4, according to one embodiment of the invention a MEMS device may be provided including a first substrate 30 with cavities 48 formed therein and secured to a second substrate 50. An electrode 56 may be provided in the first substrate 50 with an associated integrated circuit so that a magnetic field produced by the electrode 56 may cause the micromirror 60 to be deflected into a cavity 48 formed in the first substrate 30. A light 200 may be provided to reflect more or less light off of the micro mirror 60 when the micromirror 60 is deflected into the cavity 48.

The method according to the present invention may be utilized to make MEMS devices such as a digital micromirror device. A digital micro mirror device chip may be the world's most sophisticated light switch. It may contain an array of 750,000 to 1.3 million pivotally mounted microscopic mirrors. Each mirror may measure less than one fifth of the width of a human hair and corresponds to one pixel in a projected image. The digital micromirror device chip can be combined with a digital video or graphics signal, a light source, and a projector lens so that the micromirror reflects an all-digital image onto a screen or another surface.

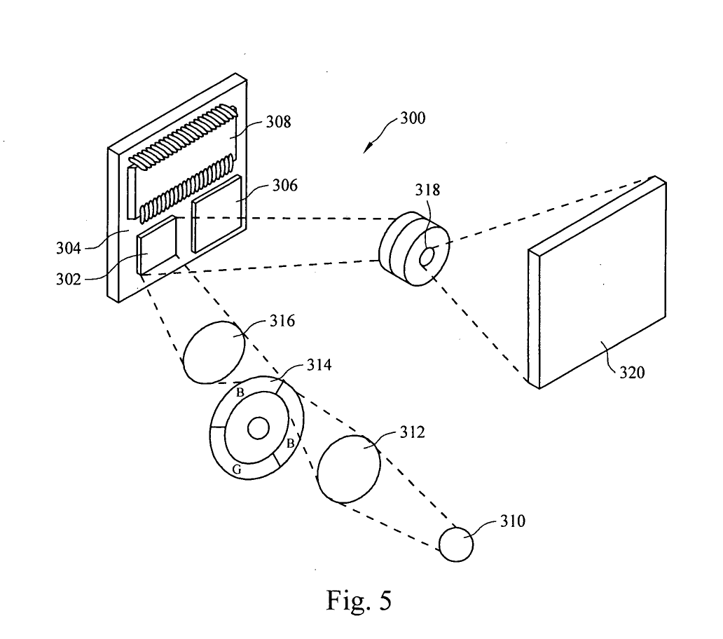

Although there are a variety of digital micromirror devices and configurations, typically micromirrors are mounted on tiny hinges that enable each mirror to be tilted either toward a light source (on) in a projector system to reflect the light or away from the light source (off) creating a darker pixel on the projected surface. A bit stream of image code entering the semiconductor directs each mirror to switch on or off several times per second. When the mirror is switched on more frequently than the mirror is off, the mirror reflects a light gray pixel. When the mirror is switched off more frequently than on, the mirror reflects a dark gray pixel. Some projector systems can deflect pixels enough to generate 1,024 shades of gray to convert the video or graphic signal entering the digital micromirror device into a highly detailed gray scale image. FIG. 5 illustrates one type of a projector system 300 that includes an array of micromirrors 302 typically formed on a semiconductor chip. The array of micromirrors 302 may be attached to a printed circuit board 304 or a similar substrate that includes the additional microelectronic devices 306, 308 to perform video processing of video or graphic signals and scaling of the image to be projected. A bright light source 310 is provided and a first optical lens 312 may be present and positioned to direct light from the light source 310 through a color wheel 314. A color wheel 314 includes transparent sections with different color filters, such as red, green, and blue filters. Additional color filters and clear sections may be provided on the color wheel 314 if desired. Light emitted from (or passing through) the color wheel 314 may be focused on a second optical lens 316 and onto the array of micromirrors 302 so that each micromirror is operated to selectively reflect (or not) the light projected thereon. Light reflected from the array of micromirrors 302 may be focused by a third optical lens 318 onto a wall or screen 320. Alternatives to using the color wheel 314 to produce a color image, such as prisms are known to those skilled in the art.

When the terms “overlying”, “overlie”, “over” and the like terms are used here in regarding the position of one component of the invention with respect to another component of the invention, such shall mean that the first component may be in direct contact with the second component or that additional components such as under bump metallurgies, seed layers, or the like may be interposed between the first component and the second component.

What is claimed is:

1. A process of making a semiconductor device comprising:
providing a first substrate having a first face and a second face, and an insulator layer over the second face of the first substrate;
attaching a holder to the insulator layer;
forming a plurality of cavities in the first face of the first substrate;
bonding the first substrate to a second substrate comprising at least one integrated circuit therein.

2. A process as set forth in claim 1 wherein the first substrate comprises silicon.

3. A process as set forth in claim 1 wherein the insulator layer comprises silicon dioxide.

4. A process as set forth in claim 1 wherein the holder comprises a wafer comprising at least one of silicon, glass, ceramic and germanium.

5. A process as set forth in claim 1 wherein the first substrate comprises a wafer comprising at least one of silicon, aluminum, IIA and VA group elements.

6. A process as set forth in claim 1 wherein the second substrate comprises a wafer comprising at least one of silicon, germanium and SiGe.

7. A process as set forth in claim 1 wherein the attaching of the holder to the insulator layer comprises applying an adhesive layer to the second face of the first substrate and placing the holder on the adhesive layer.

8. A process as set forth in claim 1 wherein the bonding of the first substrate to the second substrate comprises bonding the first face of the first substrate to a first face of the second substrate.

9. A process as set forth in claim 1 wherein the bonding of the first substrate to the second substrate comprises ultrasonic bonding.

10. A process as set forth in claim 1 wherein the first substrate comprises a plurality of micromirrors and at least one torsion hinge connecting one of the micromirrors for pivotal movement and so that at least a portion of one of the micromirrors is deflectable into one of the cavities formed in the first substrate.

11. A process as set forth in claim 10 wherein the insulator layer does not cover the micromirror.

12. A process as set forth in claim 10 wherein the insulator layer covers the micromirror.

13. A process as set forth in claim 1 further comprising removing the holder after the bonding of the first substrate to the second substrate.

14. A method as set forth in claim 13 wherein the step of removing of the holder comprises at least on of a UV and thermal release process.

15. A process as set forth in claim 1 further comprising forming, in the first substrate, a micromirror and a torsion hinge connected to the micromirror by selectively etching portions of the first substrate over one of the cavities so that a space separates the micromirror from the rest of the first substrate with the exception of the torsion hinge.

16. A process as set forth in claim 1 further comprising thinning the first substrate prior to forming the plurality of cavities in the first substrate.

17. A process as set forth in claim 16 wherein the thinning comprises chemical mechanical planarization of the first substrate.

18. A process as set forth in claim 16 wherein the thinning comprises at least one of grinding and plasma thinning.

19. A process as set forth in claim 16 wherein the forming of the plurality of cavities in the first substrate comprises depositing and patterning a photoresist layer over a third face of the first substrate formed by the thinning of the first substrate so that the patterned photoresist layer has a plurality of opening therein exposing portions of the third face of the first substrate, and etching the first substrate through the plurality of openings in the photoresist layer to form the plurality of cavities.

20. A process as set forth in claim 1 wherein the attaching of the holder to the insulator layer comprises applying an adhesive layer to the second face of the first substrate and placing the holder on the adhesive layer and wherein the holder comprises a wafer comprising silicon, and after the bonding of the first substrate to the second substrate, and etching away the holder and the adhesive layer.

21. A process of making a semiconductor device comprising:
providing a first substrate comprising a bottom face and a top face, and an insulator layer overlying the top face of the first substrate;
attaching a holder wafer to the insulator layer;
thinning the first substrate to provide a post thinning third face;
forming a plurality of cavities in the first substrate;
bonding the first substrate to a second substrate, and wherein the plurality of cavities are closest to the second substrate.

22. A process as set forth in claim 21 wherein the thinning of the first substrate comprises chemical mechanical planarization of the first substrate.

23. A process as set forth in claim 21 wherein a second substrate comprises a plurality of integrated circuits defined therein and at least one electrode positioned to underlie one of the cavities in the first substrate.

24. A process as set forth in claim 21 further comprising removing the holder wafer.

25. A process as set forth in claim 21 further comprising removing the holder wafer and forming a plurality of micromirrors in the first substrate, and wherein the micromirrors are pivotally connected so that at least one of the micromirrors may be deflected into one of the cavities formed in the first substrate.

26. A process as set forth in claim 21 wherein the insulator layer comprises silicon dioxide.

27. A process of making semiconductor device comprising:
providing a first substrate comprising silicon, the first substrate having a bottom face and a top face;
providing an insulator layer comprising silicon dioxide overlying the top face of the first substrate;
applying an adhesive layer over the insulator layer and placing a holder wafer on the adhesive layer and allowing the adhesive layer to cure;
thinning the first substrate to provide a post thinning third face;
forming a plurality of cavities in the first substrate leaving portions of the third face of the first substrate;
bonding the first substrate to a second substrate comprising a semiconductor wafer including a plurality of integrated circuits defined therein and the second substrate including at least one electrode positioned to underlie one of the cavities formed in the first substrate.

28. A process as set forth in claim 28 wherein the bonding of the first substrate to the second substrate comprises at least one of plasma activation of the surfaces of the first substrate and the second substrate, and ultrasonic bonding.

30. A process as set forth in claim 28 further comprising removing the holder wafer and adhesive layer after the bonding of the first substrate to the second substrate.

31. A process as set forth in claim 30 further comprising removing portions of at least one of the insulator layer and the first substrate overlying at least one of the cavities to provide a pivotally movable micromirror.
